(19) United States
(12) Patent Application Publication
(10) Pub. No.: US 2009/0187807 A1
(43) Pub. Date: Jul. 23, 2009

(54) METHOD FOR OPTIMIZING BLOCK CODING PARAMETERS, A COMMUNICATIONS CONTROLLER EMPLOYING THE METHOD AND A COMMUNICATIONS NODE AND LINK EMPLOYING THE CONTROLLER

(75) Inventors: Rajan L. Narasimha, Champaign, IL (US); Nirmal C. Warke, Irving, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/359,231

(22) Filed: Jan. 23, 2009

Related U.S. Application Data
(60) Provisional application No. 61/022,846, filed on Jan. 23, 2008.

(51) Int. Cl. H03M 13/17; G06F 11/07

(52) U.S. Cl. 714/761; 714/E11.021

(57) ABSTRACT

A method of determining optimal FEC configuration parameters, a communications controller, a communications link and a communications node is disclosed. In one embodiment, the communications controller, includes: (1) a processor, (2) a communications system information collector configured to receive operational information from a communications system having a block encoder, a block decoder and a decision feedback equalizer, (3) a code determiner configured to employ the operational information to select, from a set of candidate codes, a random error correction code or a burst error correction code that has a least error correction capability and satisfies a target performance specification for the communications system and (4) a parameter selector configured to select configuration parameters associated with the selected random error correction code or the selected burst error correction code and send the selected configuration parameters to the block encoder and the block decoder.

### CROSS-REFERENCE TO RELATED APPLICATION

This application claims the benefit of U.S. Provisional Application Ser. No. 61/022,846, filed by Rajan L. Narasimha, et al., on Jan. 23, 2008, entitled “Methodology for Design of FEC in SerDes Applications,” commonly assigned with this application and incorporated herein by reference in its entirety.

### TECHNICAL FIELD

This application is directed, in general, to communication links and, more specifically, to optimizing the performance of communication links such as a SerDes link.

### BACKGROUND

Intersymbol interference (ISI) occurs in communication systems when adjoining symbols in a communication signal interfere with one another. Like noise, ISI can cause distortion of the communication signal and introduce errors at a receiver. ISI can be caused by the communication system itself such as by a band-limiting channel, reflections from connectors, vias and stubs. Therefore, to deliver data with a low bit error rate (BER), communication systems can be designed to minimize the effects of ISI. When not addressed, ISI can impose a BER floor that is undesirable.

### SUMMARY

One aspect provides communications controller. In one embodiment, the communications controller, includes: (1) a processor, (2) a communications system information collector configured to receive operational information from a communications system having a block encoder, a block decoder and a decision feedback equalizer, (3) a code determiner configured to employ the operational information to select, from a set of candidate codes, a random error correction code or a burst error correction code that has a least error correction capability and satisfies a target performance specification for the communications system and (4) a parameter selector configured to select configuration parameters associated with the selected random error correction code or the selected the burst error correction code and send the selected configuration parameters to the block encoder and the block decoder.

Another aspect provides a method of determining FEC configuration parameters for a SerDes link having a DFE. In one embodiment, the method includes: (1) employing initial configuration parameters in an FEC encoder and decoder of a SerDes link, (2) obtaining operational information of the SerDes link, (3) employing the operational information to provide a model of error state probabilities associated with error propagation from the decision feedback equalizer, (4) determining error statistics for each random error correction code of a set of candidate codes employing the model, (5) determining burst length statistics for each burst error correction code of the set of candidate codes employing the model and (6) selecting one of a random error correction code and a burst error correction code from the set of candidate codes that optimizes performance of the SerDes link.

Yet another aspect provides a SerDes link. In one embodiment, the SerDes link includes: (1) a FEC layer, (2) a DFE and (3) a communications controller, having: (3A) an information collector configured to receive operational information from the SerDes communication link, (3B) a code determiner configured to employ the operational information to select, from a set of candidate codes, a random error correction code or a burst error correction code that has a least error correction capability and satisfies a target performance specification for the SerDes communication link and (3C) a parameter selector configured to select configuration parameters associated with the selected random error correction code or the selected burst error correction code and send the selected configuration parameters to the forward error correction layer.

In still yet another aspect, a node of a communications network is provided. In one embodiment, the node includes: (1) multiple processors configured to direct data across the communications network, wherein the multiple processors communicate data therebetween via SerDes communication links including a FEC layer and a DFE and (2) a communications controller configured to optimize performance of the SerDes communication links. The communications controller having: (2A) an information collector configured to receive operational information from the SerDes communication links, (2B) a code determiner configured to employ the operational information to select, from a set of candidate codes, a random error correction code or a burst error correction code that has a least error correction capability and satisfies a target performance specification for the SerDes communication links and (2C) a parameter selector configured to select configuration parameters associated with the selected random error correction code or the burst error correction code and send the selected configuration parameters to the forward error correction layer of the SerDes communication links.

### BRIEF DESCRIPTION

Reference is now made to the following descriptions taken in conjunction with the accompanying drawings, in which:

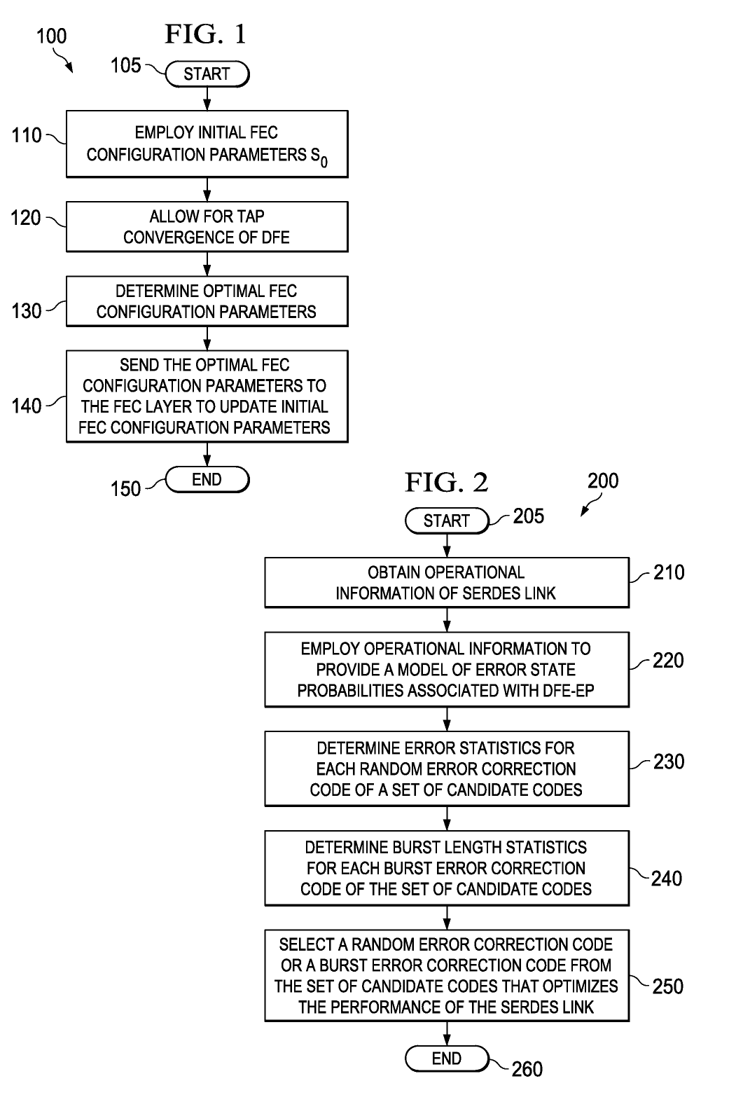

FIG. 1 illustrates a flow diagram of an embodiment of a method for updating FEC configuration parameters carried out according to the principles of the disclosure;

FIG. 2 illustrates a flow diagram of an embodiment of a method for determining optimal FEC configuration parameters carried out according to the principles of the disclosure;

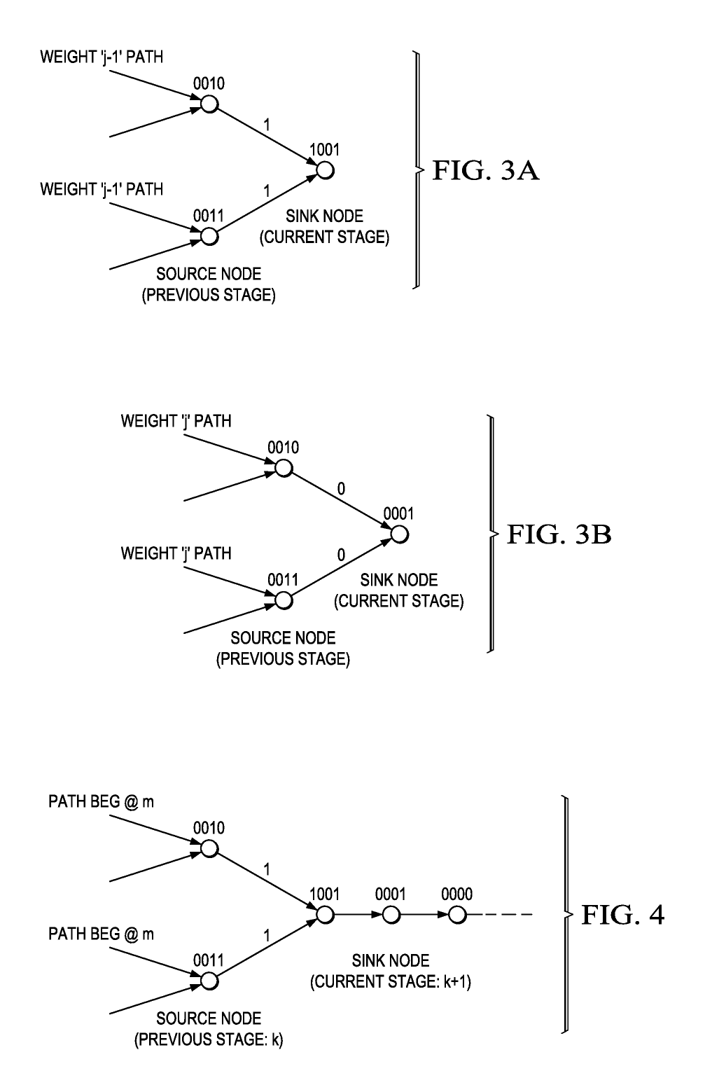

FIG. 3A and FIG. 3B illustrate trellises that represent determining error statistics for random error correction codes;

FIG. 4 illustrate a trellis that represents determining burst length statistics for burst error correction codes;

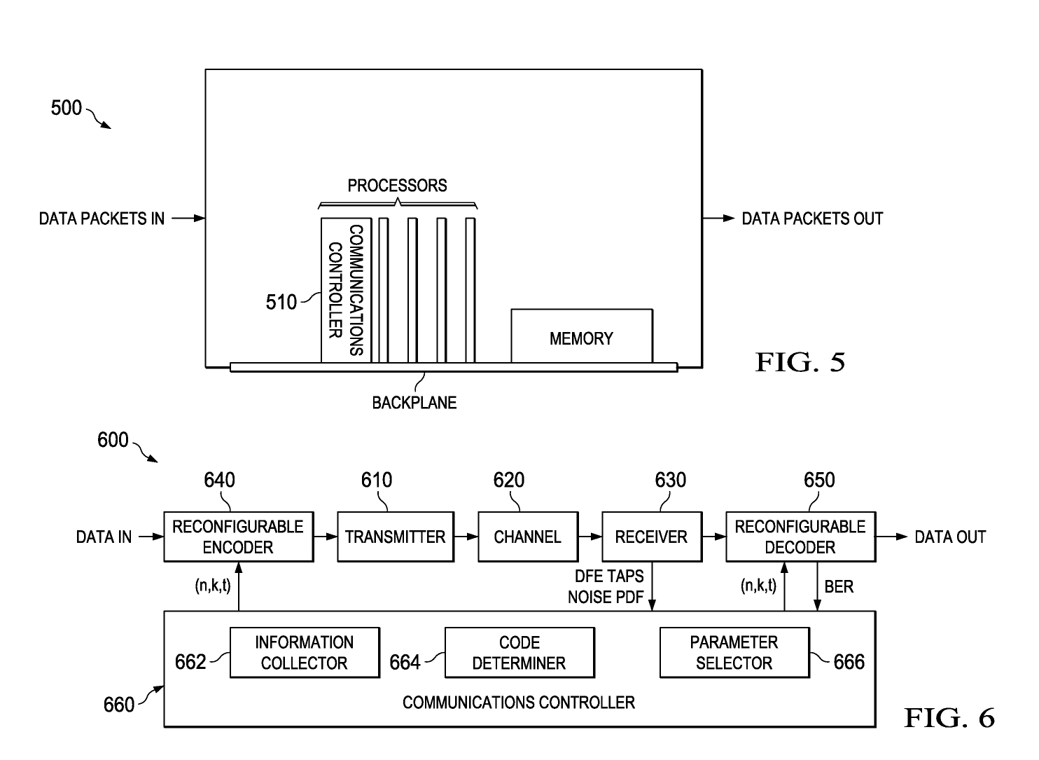

FIG. 5 illustrates a block diagram of an embodiment of a node of a communications network constructed according to the principles of the disclosure; and

FIG. 6 illustrates a block diagram of an embodiment of a SerDes link constructed according to the principles of the disclosure.

### DETAILED DESCRIPTION

Adaptive equalization can be used to reduce the effects of ISI in communication systems. For example, in Serializer/Deserializer (SerDes) applications, a Decision Feedback Equalizer (DFE) can be employed to reduce the effects of ISI that can lead to an improved BER. The desire for higher data rates and the use of longer channels, however, can cause an increase in the complexity of the DFE required to meet BER performance specifications. Alternatively, instead of increasing the complexity of the DFE, error correcting coding such as Forward Error Correction (FEC), can be added to a SerDes application. The additional FEC layer can be added for DFE complexity to allow more data to be pushed through long channels with the existing link architectures.

In addition to the desire for higher data rates and the use of longer channels, stringent power budgets are being applied to the input/output supporting blocks of the communications systems. As such, communication techniques having optimal power designs are also desired.

As such, the disclosure provides a method to update FEC configuration parameters including determining the optimal code parameters for FEC. Additionally, a communications system having an encoder and a decoder for FEC in addition to a DFE is disclosed. With the FEC, a DFE with lower complexity (e.g., a reduced number of taps) can be used while still achieving a desired BER, such as a BER of 10⁻¹⁵. Furthermore, a communications controller having the necessary circuitry to perform the disclosed methods is disclosed. The communications controller can determine the optimal parameters for the encoder and the decoder. Since channel conditions can change due to such variations as manufacturing tolerance, temperature, humidity, etc., the communications controller can determine optimal parameters to use for reconfigurable error correction. The communications controller can gather real time information (BER, DFE taps, etc.) from the communications system to determine the parameters needed for FEC to provide optimal power designs and still achieve a BER within a desired range.

FIG. 1 illustrates a flow diagram of an embodiment of a method 100 for updating FEC configuration parameters carried out according to the principles of the disclosure. The FEC configuration parameters may be employed in a SerDes communication link having a DFE. The method 100 begins in a step 105.

In a step 110, initial FEC configuration parameters are employed in a FEC layer. The initial configuration parameters are selected to provide a target performance of the SerDes link within a determined range. For example, the target performance specified for the SerDes communication link may be a BER that is specified to be less than 10⁻¹⁵. An acceptable range for the BER may be between 10⁻¹² and 10⁻¹⁵. The initial configuration parameters that are used, therefore, may provide a BER between 10⁻¹² and 10⁻¹⁵ for communicating over the SerDes link.

The FEC layer may be an encoder and a decoder of the SerDes link. The configuration parameters may include a codeword length (n), a data word length (k) and an error correction capability (t). The configuration parameters may also include interleaving depths that can be used with encoding of parallel streams before serialization in high performance SerDes links.

After employing the initial configuration parameters, the taps of the DFE are allowed to converge in a step 120. Convergence allows the taps of the DFE to settle-in before obtaining information therefrom. In a step 130, optimal FEC configuration parameters are determined. Even though the initial configuration parameters may provide an acceptable performance, optimal parameters can increase the target performance within acceptable range or provide an acceptable target performance with a lower power requirement. FIG. 2 provides more detail of an embodiment of determining optimal FEC configuration parameters.

After determining the optimal configuration parameters, the optimal configuration parameters are sent to the FEC layer to update the initial FEC configuration parameters in a step 140. The method 100 then ends in a step 150.

FIG. 2 illustrates a flow diagram of an embodiment of a method 200 for determining optimal FEC configuration parameters carried out according to the principles of the disclosure. The FEC configuration parameters may be employed in a SerDes communication link having a DFE. The method 200 begins in a step 205.

In a step 210, operational information of a SerDes link is obtained. The operational information may include a tap weights of the DFE, a probability density function of effective noise associated with the DFE and a BER of a received signal. The DFE tap weights and the probability density function of effective noise associated with the DFE may be obtained from a receiver of the SerDes link. The probability density function of effective noise associated with the DFE may be provided from a simulation platform that models the voltage, timing and residual ISI noise of the SerDes link. The model provided by the simulation platform may be based on ideal feedback conditions. The BER may be obtained from a FEC layer decoder of the SerDes link. As indicated, the operational information may include real time information.

After obtaining the operational information, the operational information is employed to provide a model of error state probabilities associated with error propagation from the DFE in a step 220. A Markov chain can be used to model the error state probabilities. Those skilled in the art are familiar with modeling error state probabilities using a Markov chain such as described in “An Upper Bound On The Error Probability In Decision-Feedback Equalization,” by D. L. Duttweiler, et al., IEEE Trans. Inform. Theory IT-20 (4) (July 1974), pp. 490-497.

Error statistics for each random error correction code of a set of candidate codes are determined employing the model in a step 230. The error statistics for random errors may be represented by Rⱼ^{k}(i) where an event ‘k’ length sequence ends in state ‘i’ AND has weight ‘j.’ Different random error scenarios may be captured and tracked using a weighted ‘j’ path probability recursion. For example, if a new_error_bit=

1: Prⱼ^{k+1}(i)=Prⱼ₋₁^{k}(to(i,1))*Pr(to(i,1)→i)+Prⱼ₋₁^{k}(to(i,2))*Pr(to(i,2)→i) (Equation 1)

0: Prⱼ^{k+1}(i)=Prⱼ^{k}(to(i,1))*Pr(to(i,1)→i)+Prⱼ^{k}(to(i,2))*Pr(to(i,2)→i) (Equation 2).

FIG. 3A illustrate a trellis that represents Equation 1, and FIG. 3B illustrates a trellis that represents Equation 2. In FIG. 3A, the weight ‘j−1’ is used and in FIG. 3B the weight ‘j’ is used. The probability of the occurrence of random errors for a particular code (ncode) of the candidate codes can be represented by the following equation:

$${Pr}_{j}^{ncode} = {\sum }_{i}^{ } {Pr}_{j}^{ncode} ( i ) . \qquad ( Equation 3 )$$

In some embodiments, determining the error statistics for each random error correction code may be repeated for each choice of interleaving depths that is included in the set of candidate codes. By merging adjacent stages in the trellises of FIGS. 3A and 3B, error statistics in the case of interleaved links can be determined. For example, formulating a recursion between stage “k+2” and “k” can be used to model interleaving by a factor of two.

In a step 240, burst length statistics for each burst error correction code of the set of candidate codes are determined employing the model. The error statistics for burst errors may be represented by Bⱼ^{k}(i) where an event ‘k’ length sequence ends in state ‘i’ and has a burst error length ‘j.’ Different burst error scenarios may be captured and tracked using a burst length ‘j’ path probability recursion. For example, the below equations and the corresponding trellis of FIG. 4A may be used to determine burst length statistics.

Pr_begₘ^{k+1}(i)=Pr_begₘ^{k}(to(i,1))*Pr(to(i,1)→i)+Pr_begₘ^{k}(to(i,2))*Pr(to(i,2)→i) (Equation 4)

Prⱼ^{k+1}(i)=Pr_begₖ₊₂₋ⱼ^{k+1}(i)*Pr(‘i’ followed by ‘0’ s)+Prⱼ^{k}(i) (Equation 5).

After determining the error statistics and the burst length statistics, a random error correction code or a burst error correction code are selected in a step 250 from the set of candidate codes that optimizes performance of the SerDes link. Performance of the SerDes link may be optimized by a code that has minimum error correction capability and still satisfies a target performance specification. The random error correction code or the burst error correction code may be optimal codes for the SerDes link. The configuration parameters of the code that is selected can then be used in the FEC layer of the SerDes link to optimize the performance thereof. The method 200 then ends in a step 260.

The disclosure demonstrates estimating a post-FEC BER based on FEC code parameters and the distribution of error statistics. In a specific case of a SerDes link with a DFE, which is often employed in high speed LR applications, the disclosure provides determining error statistics with a DFE. The code parameters determined when estimating post-FEC BER can be used to optimize the performance of input/output communication links such as SerDes links. One example commonly employing SerDes links is a router or server of a communications network.

FIG. 5 illustrates a block diagram of an embodiment of a node 500 of a communications network constructed according to the principles of the disclosure. The communications network may be the Internet and the node 500 may be a server or a router of the communications network. The node 500 may include at least one memory and multiple processors that communicate therebetween to direct received data packets to destinations of the communications network. The memory and processors may communicate via a channel such as the backplane. Each of the processors and the memory may communicate via the backplane employing a SerDes link. The node 500, therefore, can have multiple SerDes links that are used for communicating over the backplane.

Both the memory and the processors may operate at high speeds. As such, the backplane, which is often a copper trace, may be the weak link in communications between the processors and the processors and the memory. Accordingly, optimization of the SerDes links may prove beneficial in communications between the components of the node 500.

The node 500, therefore, includes a communications controller 510 configured to reconfigure the coding parameters of the SerDes links as described in FIGS. 1 and 2 to optimize the performance of the SerDes links. The communications controller 510 may be implemented as a processor or at least part of a processor. The communications controller may be embodied as a series of operating instruction stored on a computer readable storage medium that direct the operation of the processor when executed. The communications controller 510 may optimize the performance of one or multiple of the SerDes links of the node 500. An example of a SerDes link such as from the node 500 and a communications controller are discussed in more detail in FIG. 6.

FIG. 6 illustrates a block diagram of an embodiment of a SerDes link 600 constructed according to the principles of the disclosure. The SerDes link 600 includes a transmitter 610, a channel 620, a receiver 630, a reconfigurable encoder 640, a reconfigurable decoder 650 and a communications controller 660. The transmitter 610, channel 620 and receiver 630 may be conventional components of a SerDes communication link that employs DFE, such as a SerDes link of the node 500. The SerDes link 600 may include additional components or devices that are typically included in such a communications link.

The reconfigurable encoder 640 is configured to provide block coding for the SerDes link 600. The reconfigurable decoder 650 is configured to provide decoding associated with the block coding of the reconfigurable encoder 640. The reconfigurable encoder 640 and the reconfigurable decoder 650 may be part of a FEC layer of the SerDes link 600.

Both the reconfigurable encoder 640 and the reconfigurable decoder 650 employ configuration parameters for encoding and decoding. The configuration parameters may include a codeword length (n), a data word length (k) and an error correction capability (t). The configuration parameters may also include interleaving depths that can be used with encoding of parallel streams before serialization in high performance SerDes links. The configuration parameters may be updated to optimal parameters by the communications controller 660.

The communications controller 660 is configured to optimize the performance of the SerDes link 600. For example, the communications controller 660 may reduce the effect of ISI associated with the SerDes link 600. In one embodiment, the communications controller 660 may be a dedicated device constructed of special purpose hardware. The communications controller 660 includes a communications system information collector 662, a code determiner 664 and a parameter selector 666. The communications controller 660 may include a processor that is employed to perform the functions of the communications system information collector 662, the code determiner 664 and the parameter selector 666.

The communications system information collector 662 is configured to receive operational information from the SerDes link 600. The operational information may include tap weights of the DFE (in the receiver 630) of the SerDes link 600, a probability density function of effective noise associated with the DFE and a BER of a received signal of the SerDes link 600.

The code determiner 664 is configured to employ the operational information to select, from a set of candidate codes, either a random error correction code or a burst error correction code that optimizes the performance of the SerDes link 600. For example, the code determiner 664 may select one of the error correction codes that has a least error correction capability and also satisfies a target performance specification for the communications system. The set of candidate codes may be stored in the code determiner. The code determiner 664 may be configured to employ at least some of the operational information to provide a model of error state probabilities associated with error propagation from the DFE. A Markov chain model may be used to model the error state probabilities.

Additionally, the code determiner 664 may employ at least some of the operational information and the model to determine error statistics for each random error correction code of the set of candidate codes. In some embodiments, the code determiner 664 may be configured to determine error statistics of each of the random error correction codes for each interleaving depth stored with the set of candidate codes. The code determiner 664 may also employ at least some of the operational information and the model to determine burst length statistics for each burst error correction code of the set of candidate codes.

The parameter selector 666 is configured to select configuration parameters associated with the selected random error correction code and the burst error correction code and send the selected configuration parameters to the reconfigurable encoder 640 and the reconfigurable decoder 650. The selected configuration parameters may include a codeword length, a data word length and an error correction capability.

In some embodiments, the selected configuration parameters may also include interleaving depths. Additionally, in some embodiments, one of the system information collector 662, the code determiner 664 or the parameter selector 666 may be configured to also perform functions designated to another one thereof. For example, in one embodiment the parameter selector 666 may also be configured to select one of the burst error or random error correction codes.

The above-described methods may be embodied in or performed by various conventional digital data processors or computers, wherein the computers are programmed or store executable programs of sequences of software instructions to perform one or more of the steps of the methods, e.g., steps of the method of FIG. 1 or 2. The software instructions of such programs may be encoded in machine-executable form on conventional digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, e.g., one or more of the steps of the method of FIG. 1 or 2. Additionally, an apparatus, such as a communications controller, may be designed to include the necessary circuitry to perform each step of the methods of FIG. 1 or 2.

Those skilled in the art to which this application relates will appreciate that other and further additions, deletions, substitutions and modifications may be made to the described embodiments.

What is claimed is:

1. A communications controller, comprising:
a processor;
a communications system information collector configured to receive operational information from a communications system having a block encoder, a block decoder and a decision feedback equalizer;
a code determiner configured to employ said operational information to select, from a set of candidate codes, a random error correction code or a burst error correction code that has a least error correction capability and satisfies a target performance specification for said communications system; and
a parameter selector configured to select configuration parameters associated with said selected random error correction code or said selected burst error correction code and send said selected configuration parameters to said block encoder and said block decoder.

2. The communications controller as recited in claim 1 wherein said communications system is a SerDes link and said block encoder and said decoder are a forward error correction encoder and decoder.

3. The communications controller as recited in claim 2 wherein said operational information includes tap weights of said decision feedback equalizer, a probability density function of effective noise associated with said decision feedback equalizer and a bit error rate of a received signal of said SerDes link.

4. The communications controller as recited in claim 1 wherein said code determiner is configured to employ at least some of said operational information to provide a model of error state probabilities associated with error propagation from said decision feedback equalizer.

5. The communications controller as recited in claim 4 wherein said code determiner is further configured to employ at least some of said operational information and said model to determine error statistics for each random error correction code of said set of candidate codes.

6. The communications controller as recited in claim 5 wherein said code determiner is further configured to determine error statistics for said each random error correction code for each interleaving depth of said set of candidate codes and employ at least some of said operational information and said model to determine burst length statistics for each burst error correction code of said set of candidate codes.

7. The communications controller as recited in claim 1 said configuration parameters include at least one of:
a codeword length, a data word length and an error correction capability; and
interleaving depths.

8. A method of determining FEC configuration parameters for a SerDes link having a decision feedback equalizer, comprising:
employing initial configuration parameters in an FEC encoder and decoder of a SerDes link;
obtaining operational information of said SerDes link;
employing said operational information to provide a model of error state probabilities associated with error propagation from said decision feedback equalizer;
determining error statistics for each random error correction code of a set of candidate codes employing said model;
determining burst length statistics for each burst error correction code of said set of candidate codes employing said model; and
selecting one of a random error correction code and a burst error correction code from said set of candidate codes that optimizes performance of said SerDes link.

9. The method as recited in claim 8 further comprising sending selected configuration parameters of said selected random error correction code or said selected burst error correction code to said FEC encoder and decoder to update said initial configuration parameters.

10. The method as recited in claim 8 wherein said configuration parameters include a codeword length, a data word length and an error correction capability.

11. The method as recited in claim 8 wherein said configuration parameters include interleaving depths.

12. The method as recited in claim 8 further comprising determining error statistics for said each random error correction code for each interleaving depth of said set of candidate codes.

13. The method as recited in claim 8 wherein said operational information includes tap weights of said decision feedback equalizer, a probability density function of effective noise associated with said decision feedback equalizer and a bit error rate of a received signal.

14. A SerDes communication link, comprising:
a forward error correction layer;
a decision feedback equalizer; and
a communications controller, including:
an information collector configured to receive operational information from said SerDes communication link,
a code determiner configured to employ said operational information to select, from a set of candidate codes, a random error correction code or a burst error correction code that has a least error correction capability and satisfies a target performance specification for said SerDes communication link, and
a parameter selector configured to select configuration parameters associated with said selected random error correction code or said selected burst error correction code and send said selected configuration parameters to said forward error correction layer.

15. The communications controller as recited in claim 14 wherein said forward error correction layer includes an encoder and a decoder.

16. The communications controller as recited in claim 14 wherein said operational information includes tap weights of said decision feedback equalizer, a probability density function of effective noise associated with said decision feedback equalizer and a bit error rate of a received signal of said SerDes link.

17. The communications controller as recited in claim 14 wherein said code determiner is configured to employ at least some of said operational information to provide a model of error state probabilities associated with error propagation from said decision feedback equalizer.

18. The communications controller as recited in claim 17 wherein said code determiner is further configured to employ at least some of said operational information and said model to determine error statistics for each random error correction code of said set of candidate codes.

19. The communications controller as recited in claim 18 wherein said code determiner is further configured to determine error statistics for said each random error correction code for each interleaving depth of said set of candidate codes and employ at least some of said operational information and said model to determine burst length statistics for each burst error correction code of said set of candidate codes.

20. The communications controller as recited in claim 14 wherein said configuration parameters include at least one of:
a codeword length, a data word length and an error correction capability; and
interleaving depths.

21. A node of a communications network, comprising:
multiple processors configured to direct data across said communications network, wherein said multiple processors communicate data therebetween via SerDes communication links including a forward error correction layer and a decision feedback equalizer; and
a communications controller including:
an information collector configured to receive operational information from said SerDes communication links;
a code determiner configured to employ said operational information to select, from a set of candidate codes, a random error correction code or a burst error correction code that has a least error correction capability and satisfies a target performance specification for said SerDes communication links; and
a parameter selector configured to select configuration parameters associated with said selected random error correction code or said selected burst error correction code and send said selected configuration parameters to said forward error correction layer of said SerDes communication links.
